(19) United States
(12) Patent Application Publication
(10) Pub. No.: US 2014/0061742 A1
(43) Pub. Date: Mar. 6, 2014

(54) SEMICONDUCTOR DEVICE

(71) Applicant: Elpida Memory, Inc., Tokyo (JP)

(72) Inventors: Junichiro NISHITANI, Tokyo (JP); Hirotoshi SEKI, Tokyo (JP); Kenji WATANABE, Tokyo (JP)

(21) Appl. No.: 13/944,296

(22) Filed: Jul. 17, 2013

(30) Foreign Application Priority Data
Sep. 4, 2012 (JP) 2012-193751

(51) Int. Cl. H01L 27/088; H01L 29/06; H01L 27/07

(52) U.S. Cl. CPC H01L 27/088; H01L 27/0733; H01L 29/0603
USPC 257/296; 257/334; 257/506

(57) ABSTRACT

A semiconductor device comprises an isolation region, an active region, a first gate trench extending continuously from the active region to the isolation region, first and second insulating films, a first conductive layer, and a cap insulating film. The first insulating film covers an inner surface of the first gate trench. The second insulating film interposes between the first insulating film and the inner surface of the first gate trench at the active region. The first conductive layer buries a lower portion of the first gate trench so as to cover at least a part of the first insulating film. The cap insulating film covers the upper surface of the first conductive layer and buries an upper portion of the first gate trench

This application is based upon and claims the benefit of priority from Japanese Patent Application No. 2012-193751 filed on Sep. 4, 2012, the disclosure of which are incorporated herein in its entirety by reference.

### BACKGROUND OF THE INVENTION

1. Field of the Invention

The present invention relates to a semiconductor device.

2. Description of the Related Art

Conventionally, there has been used a semiconductor device with an isolation region (STI: Shallow Trench Isolation) formed by burying an insulating film in a trench provided in a semiconductor substrate. In this semiconductor device, a region segmented by STI serves as an active region. In addition, in order to elongate the gate length of a transistor, there has been conventionally used a method that includes forming gate trenches in a semiconductor substrate, in addition to trenches for STI, and burying gate electrodes in these gate trenches.

JP2011-159739A discloses a semiconductor device in which an active region isolated by STI is formed, and a gate electrode is formed as a buried wiring line.

The aspect ratio of a trench for STI has increased along with progress in the miniaturization of a semiconductor device (for example, a DRAM), which makes it increasingly difficult to fill this trench with an insulating film. In particular, a bowing shape is easy to occur when trenches for STI are formed.

FIG. 12 is a perspective view illustrating part of a process for manufacturing memory cell region 2 by a conventional method. Specifically, FIG. 12A illustrates a state of memory cell region 2 after isolation region 200 is formed in semiconductor substrate 100 and then etched in order to form gate trench 310. FIG. 12B illustrates a state of memory cell region 2 after gate insulating film 311 is formed on the inner walls of gate trench 310 formed in semiconductor substrate 100, barrier metal layer 312a and metal layer 312b are formed so as to fill gate trench 310, and then barrier metal layer 312a and metal layer 312b are etched back.

As illustrated in FIG. 12A, in the conventional method, a trench for STI is filled with silicon nitride film (LP-SiN film) 30a formed by an LP-CVD (Low Pressure Chemical Vapor Deposition) method and silicon oxide film (HDP-SiO₂ film) 20a formed by an HDP-CVD (high-density plasma CVD) method. Here, if the trench for STI has a bowing shape, seam E2 occurs in LP-SiN film 30a after the filling of the trench for STI.

Next, as illustrated in FIG. 12B, an exposed surface of semiconductor substrate 100 is thermally oxidized to form gate insulating film 311 made of silicon oxide film 21 on the inner surfaces of gate trench 310. Seam E2 in LP-SiN film 30a remains as is, however, even after the formation of this gate insulating film 311. Accordingly, when conductive layers, such as barrier metal layer 312a and metal layer 312b, for buried word line 300 are formed in gate trench 310, these conductive layers remain within seam E2. As a result, the conductive layers inside this seam E2 electrically short-circuit adjacent buried word lines 300 to each other, thus causing serious yield decline.

### SUMMARY

In one embodiment, there is provided a semiconductor device comprising:

an isolation region buried with a field insulator;

an active region surrounded with the isolation region;

a first gate trench extending continuously from the active region to the isolation region;

a first insulating film covering an inner surface of the first gate trench in each of the active region and the isolation region;

a second insulating film interposing between the first insulating film and the inner surface of the first gate trench at the active region;

a first conductive layer burying a lower portion of the first gate trench so as to cover at least a part of the first insulating film and having an upper surface, the upper surface being placed below a surface of the active region; and

a cap insulating film covering the upper surface of the first conductive layer and burying an upper portion of the first gate trench.

In another embodiment, there is provided a semiconductor device comprising:

an active region surrounded with a field insulator;

first and second transistors disposed in the active region, the first and second transistors including first and second gate electrodes which are buried in first and second gate trenches, respectively, each of the first and second gate trenches extending continuously from the active region to the field insulator;

a first gate insulating film covering each of inner surfaces of the first and second gate trenches, the first gate insulating film extending continuously from the active region to the field insulator; and

a second gate insulating film interposing between the first gate insulating film and the inner surface of the first gate trench and between the first gate insulating film and the inner surface of the second gate trench at the active region.

In another embodiment, there is provided a semiconductor device comprising:

an isolation region;

a field insulator including first and second trenches having respective inner surfaces, the field insulator being buried in the isolation region and a seam extending continuously from the inner surface of the first trench to the inner surface of the second trench in the field insulator;

an insulating film covering both ends of the seam; and

a first conductive layer covering the insulating film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic view illustrating a semiconductor device according to one exemplary embodiment of the present invention;

FIG. 2 is a perspective view illustrating the semiconductor device of Exemplary Embodiment 1;

FIG. 3 is a schematic view illustrating a method for manufacturing the semiconductor device according to one exemplary embodiment of the present invention;

FIG. 4 is another schematic view illustrating the method for manufacturing the semiconductor device according to one exemplary embodiment of the present invention;

FIG. 5 is yet another schematic view illustrating the method for manufacturing the semiconductor device according to one exemplary embodiment of the present invention;

FIG. 6 is still another schematic view illustrating the method for manufacturing the semiconductor device according to one exemplary embodiment of the present invention;

FIG. 7 is still another schematic view illustrating the method for manufacturing the semiconductor device according to one exemplary embodiment of the present invention;

FIG. 8 is still another schematic view illustrating the method for manufacturing the semiconductor device according to one exemplary embodiment of the present invention;

FIG. 9 is still another schematic view illustrating the method for manufacturing the semiconductor device according to one exemplary embodiment of the present invention;

FIG. 10 is still another schematic view illustrating the method for manufacturing the semiconductor device according to one exemplary embodiment of the present invention;

FIG. 11 is still another schematic view illustrating the method for manufacturing the semiconductor device according to one exemplary embodiment of the present invention; and

FIG. 12 is a schematic view used to describe problems in the related art.

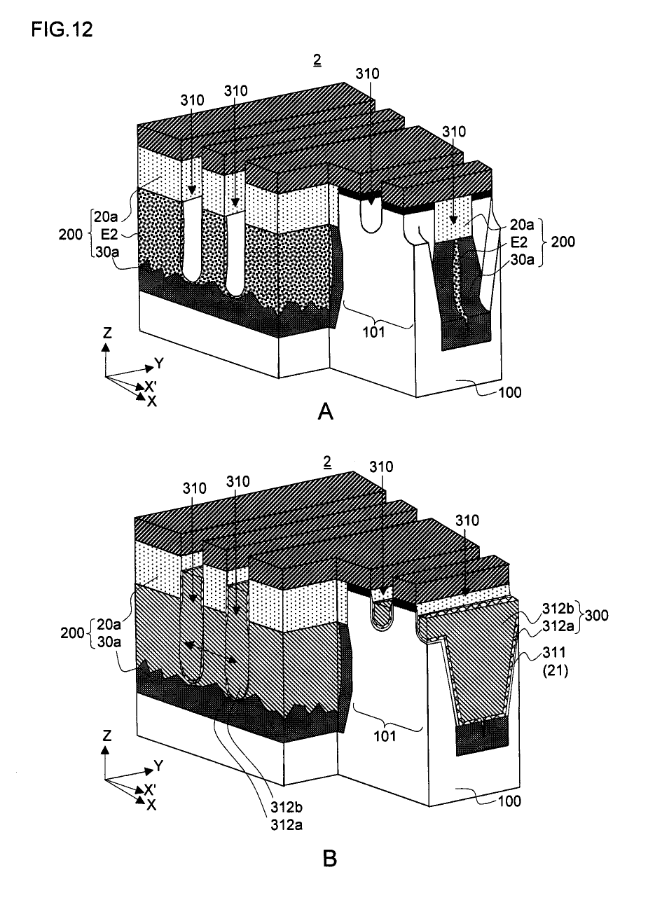

In the drawings, numerals have the following meanings, 2: memory cell region, 4A: first memory cell transistor, 4B: second memory cell transistor, 6A: first saddle fin, 6B: second saddle fin, 7: bit line contact connection region, 8A: first capacitor contact connection region, 8B: second capacitor contact connection region, 11: titanium nitride film, 12: tungsten film, 20: silicon oxide film, 22, 30: silicon nitride film, 100: semiconductor substrate, 101: active region, 102: SD diffusion layer, 103: channel, 200: isolation region, 200A: first isolation region, 200B: second isolation region, 300, 300A, 300B: buried word line, 301: mask film, 310: gate trench, 311: gate insulating film, 312a: barrier metal layer, 312b: metal layer, 312: metal word line, 313: cap insulating film, 400: first interlayer insulating film, 500: bit line, 511: bit-line contact plug, 512: lower layer of bit line, 513: upper layer of bit line, 514:

cap insulating film, 515: sidewall insulating film, 600: second interlayer insulating film, 700: capacitor contact, 780: stopper film, 790: third interlayer insulating film, 800: capacitor, 810: cylinder hole, 811: lower electrode, 812: capacitor insulating film, 813: upper electrode, 900: fourth interlayer insulating film, 910: wiring contact, 920: wiring line 930: protective insulating film, E1: side surface of isolation region, and E2: seam.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

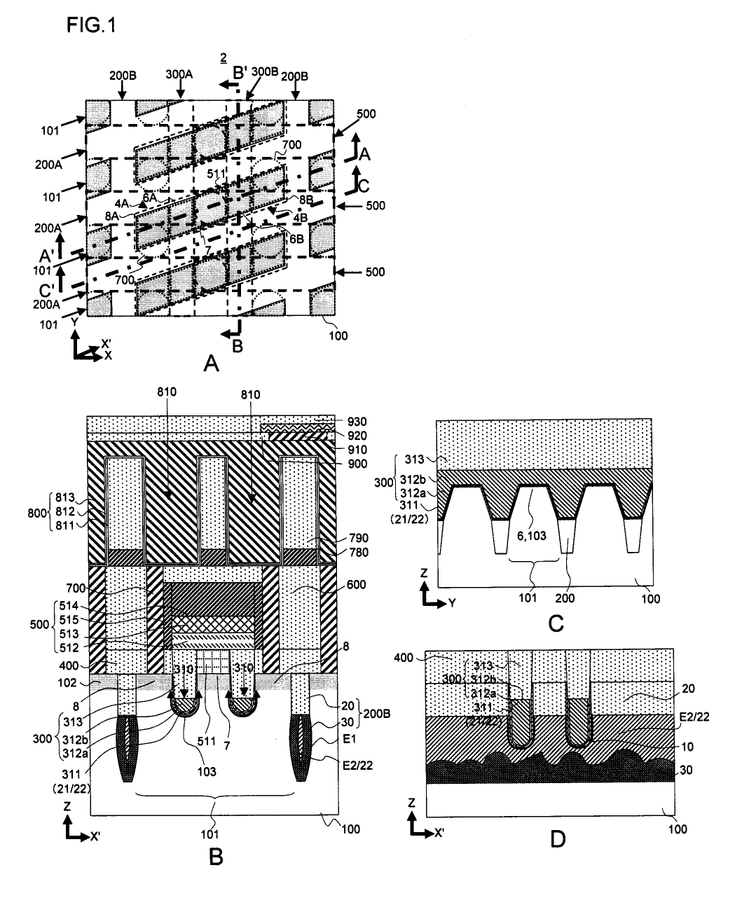

FIG. 1 is a schematic view illustrating a semiconductor device according to one exemplary embodiment of the present invention. FIG. 1A represents a plan view, whereas FIGS. 1B, 1C and 1D represent cross-sectional views respectively taken along the A-A′, B-B′ and C-C′ directions of FIG. 1A.

First, the layout of principal parts of the semiconductor device of the present exemplary embodiment will be described with reference to the plan view of FIG. 1A. The semiconductor device of the present exemplary embodiment constitutes a DRAM including memory cell region 2 formed on semiconductor substrate 100 and a peripheral circuit region arranged around the memory cell region, though only part of memory cell region 2 is shown in FIG. 1. In the present exemplary embodiment, the semiconductor device will be described considering semiconductor substrate 100 as a p-type silicon monocrystal substrate. The semiconductor substrate is not limited to this type, however, but may be an n-type silicon monocrystal substrate, a compound semiconductor substrate, or the like.

Memory cell region 2 includes first isolation regions 200A extending in an X′ direction (third direction) inclined in an X direction (second direction), second isolation regions 200B extending in a Y direction (first direction) perpendicular to the X direction, and island-shaped active regions 101. The island-shaped active regions 101 is isolated in the Y direction by first isolation regions 200A, isolated in the X′ direction by second isolation region 200B, and made of semiconductor substrate 100. Although shown as a parallelogram having a long side in the X′ direction in FIG. 1A, active regions 101 are not limited to this shape, but may have an elongate ellipsoidal shape in which the four corners of the parallelogram are rounded. Each of a plurality of active regions 101 is the same in Y-direction width and X-direction width. In addition, active regions 101 are repetitively disposed at equal pitches in the X′ direction and the Y direction. The pitch between active regions 101 adjacent to each other in the Y direction is not limited in particular. The pitch between active regions 101 may be made either equal to or smaller than the Y-direction width of each active region 101. In the semiconductor device of the present exemplary embodiment, active regions 101 extending in the X′ direction (third direction) inclined in the X direction (second direction) in which later-described bit lines extend need to be aligned and repetitively disposed on straight lines in the Y direction.

Two buried word lines 300 (shown as first word line 300A and second word line 300B in FIG. 1A) extending linearly in the Y direction are disposed across a plurality of first isolation regions 200A and a plurality of active regions 101. Although part of the configuration of the semiconductor device is omitted in FIG. 1A, first word line 300A and second word line 300B are disposed at equal pitches between adjacent second isolation regions 200B. That is, respective second isolation regions 200B, first word line 300A, and second word line 300B are disposed so as to be the same in width and pitch. First word line 300A and second word line 300B function as the gate electrodes of transistors for which the word lines are provided. Consequently, one island-shaped active region 101 extending in the X′ direction comprises the following component:
first capacitor contact connection region (second diffusion layer) 8A adjacent to second isolation region 200B and first word line 300A;
first saddle fin 6A functioning as a channel immediately underneath first word line 300A;
bit line contact connection region (first diffusion layer) 7 placed in the active region 101 adjacent to first word line 300A and second word line 300B; second saddle fin 6B functioning as a channel immediately underneath second word line 300B; and
second capacitor contact connection region (first diffusion layer) 8B adjacent to second word line 300B and second isolation region 200B.

First memory cell transistor 4A comprises first capacitor contact connection region 8A, first word line 300A, first saddle fin 6A, and bit line contact connection region 7. In addition, second memory cell transistor 4B comprises bit line contact connection region 7, second word line 300B, second saddle fin 6B, and second capacitor contact connection region 8B. Accordingly, bit line contact connection region 7 is shared by two memory cell transistors 4A and 4B. In addition, bit line contact connection region 7 is located in active region 101 between gate trenches respectively constituting first word line 300A and second word line 300B. First and second capacitor contact connection regions 8A and 8B are located on the opposite side of each other across the two gate trenches adjacent to bit line contact connection region 7. In the present exemplary embodiment, bit line contact connection region 7 is a drain region, and first and second capacitor contact connection regions 8A and 8B respectively serve as source regions. Drain region (first diffusion layer) is placed in the active region 101 which is located between the adjacent gate trenches 310. Source regions (second diffusion layers 9 are placed in the active region 101 which are located on an opposite side of the gate trenches 310 adjacent to drain region. Note that each source region and the drain region switch positions with each other if a state of applying biases is reversed.

Bit-line contact plug 511 is provided on each bit line contact connection region 7. Although part of the configuration of the semiconductor device is omitted in FIG. 1A, there is arranged bit line 500 (hereinafter described as BL 500) connected to each bit-line contact plug 511 and extending in the X direction. Capacitor contacts 700 are respectively provided in a region surrounded by second isolation region 200B, first word line 300A and two BLs 500 and in a region surrounded by second isolation region 200B, second word line 300B and two BLs 500. Capacitor contacts 700 are electrically connected to respective capacitor contact connection regions 8. A capacitor (not illustrated) is provided on each capacitor contact 700.

Next, a reference will be made to the cross-sectional views of FIGS. 1B to 1D. Second isolation regions 200B extending in the Y direction (first direction) are disposed at equal pitches in the X direction (second direction) on the surface of semiconductor substrate 100. Second isolation regions 200B are made of silicon nitride film 30 and silicon oxide film 20. Here, as the result of progress in miniaturization, side surface E1 of isolation region 200 has a bowing shape and seam E2 occurs in the central part of silicon nitride film 30. Seam E2 is located in isolation region 200A between the adjacent gate trenches 310. Each end of seam E2 is positioned on the respective inner surfaces of the adjacent gate trenches 310. In the present exemplary embodiment, however, seam E2 is filled with a silicon oxide film (for example, silicon oxide film 22—hereinafter described as ALD-SiO₂ film 22—formed by an ALD method) superior in coverage after the opening of gate trench 310. In addition, ALD-SiO₂ film 22 grown on the inner surfaces of gate trench 310 is oxidized to serve as part of gate insulating film 311. Two gate trenches 310 are disposed at equal pitches between adjacent second isolation regions 200B. Each gate trench 310 is formed so as to be shallower than the deepest portion of first isolation region 200A (for example, to an approximately ⅔ depth) in first isolation region 200A and even shallower (for example, to an approximately ⅓ depth) in active region 101, thus forming saddle fin 6. Active region 101 underneath gate trench 310 serves as channel 103 when a cell transistor is in an ON state.

Silicon oxide film 21 (second insulating film; second gate insulating film) and ALD-SiO₂ film 22 (first insulating film; first gate insulating film) are formed in order on the inner surfaces of gate trench 310, thereby constituting gate insulating film 311. That is, silicon oxide film 21 interposes between ALD-SiO₂ film 22 and the inner surface of gate trench 310 at the active region 101. In addition, gate insulating film 311 extends continuously from the active region 101 to the isolation region 200. Metal word line 312 made of barrier metal layer 312a and metal layer 312b is buried in each gate trench 310, so as to fill the lower portion thereof. Metal word line 312 is formed so as to cover at least part of ALD-SiO₂ film 22 (first insulating film) and bury a lower portion of gate trench 310. Barrier metal layer 312a and metal layer 312b constitute a first conductive layer. The upper surface of the first conductive layer is placed below a surface of the active region 101. Cap insulating film 313 is located in the upper portion of gate trench 310, so as to cover the upper surface of metal word line 312 and fill the step between the upper surface of active region 101 and the first conductive layer. Cap insulating film 313 protrudes above the surface of semiconductor substrate 100 and buries an upper portion of gate trench 310. Barrier metal layer 312a, metal layer 312b, and cap insulating film 313 thereon formed in the lower portion of each gate trench 310 serve as buried word line (buried gate electrode) 300. As illustrated in FIG. 1B, diffusion layers 102 are formed on both sides of active region 101 across respective buried word lines 300.

First interlayer insulating films 400 are provided on semiconductor substrate 100, so as to fill the space between cap insulating films 313. On the upper surface of the first diffusion layer constituting bit line contact connection region 7, bit-line contact plug 511 (first contact plug), and lower layer 512, upper layer 513 and cap insulating film 514 of BL 500 (second conductive layer) are laminated. Bit-line contact plug 511 (first contact plug) penetrates through first interlayer insulating film 400. Lower layer 512, upper layer 513 and cap insulating film 514 are connected to the upper surface of bit-line contact plug 511 and extend in the X direction. These components are formed into a wiring shape. Note that in the present exemplary embodiment, bit-line contact plug 511 and lower layer 512 of BL 500 are formed separately from each other. Alternatively, however, bit-line contact plug 511 and lower layer 512 of BL 500 may be formed integrally with each other. Sidewall insulating film 515 made of a silicon nitride film is provided on the side surfaces of lower layer 512, upper layer 513 and cap insulating film 514 of BL 500. Lower layer 512, upper layer 513, cap insulating film 514, and sidewall insulating film 515 form BL 500.

Second interlayer insulating film 600 made of a silicon oxide film is provided on the entire surface of the semiconductor substrate, so as to cover BL 500. Capacitor contact plug 700 (second contact plug) is connected to the upper surface of the second diffusion layer constituting capacitor contact connection region 8 through second interlayer insulating film 600 and first interlayer insulating film 400. Stopper film 780 made of a silicon nitride film and third interlayer insulating film 790 made of a silicon oxide film are provided on the entire surface of the resulting structure including the upper surface of capacitor contact plug 700. Cylinder hole 810 penetrating through third interlayer insulating film 790 and stopper film 780 is created so as to reach the upper surface of capacitor contact plug 700. Then, lower electrode 811 (third conductive layer) is provided so as to cover the inner surface and bottom of cylinder hole 810. Consequently, lower electrode 811 is connected to the upper surface of capacitor contact plug 700. Capacitor insulating film 812 and upper electrode 813 are provided so as to cover the surface of lower electrode 811. Lower electrode 811, capacitor insulating film 812 and upper electrode 813 constitute capacitor 800 for a memory cell. Fourth interlayer insulating film 900 is provided so as to cover capacitor 800. Wiring contact 910 penetrating through fourth interlayer insulating film 900 is provided. Wiring line 920 is connected to the upper surface of wiring contact 910. Protective insulating film 930 is provided on the entire surface of the resulting structure, so as to cover wiring line 920.

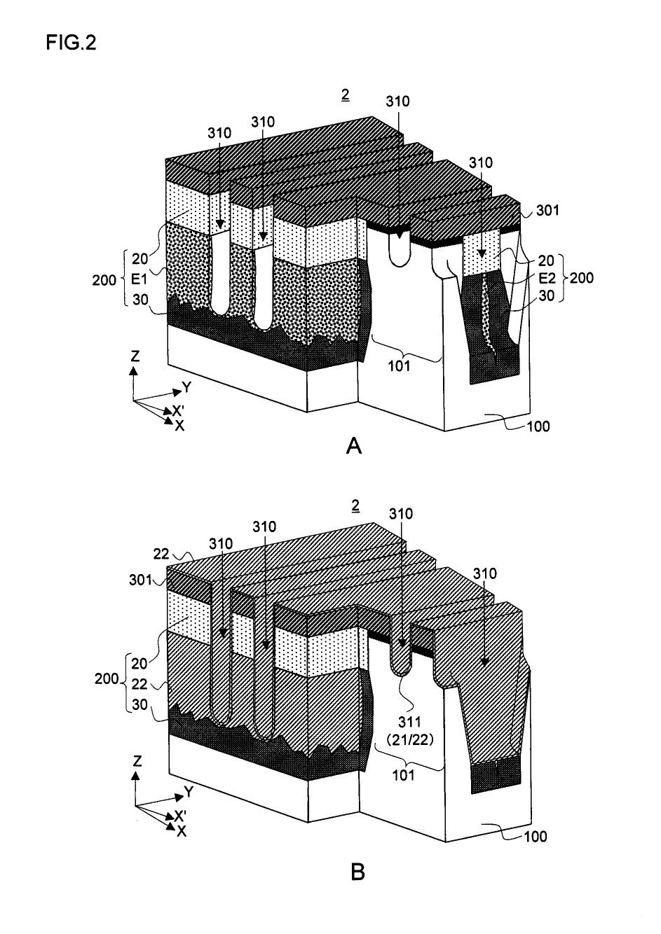

Next, the structure of the semiconductor device of the present exemplary embodiment will be described using FIGS. 2A and 2B. Note that FIG. 2 is a perspective view illustrating a manufacturing process of part of memory cell region 2, and the layout of respective principal parts is defined as conforming to those of FIGS. 1A to 1D. More specifically, FIG. 2A shows a state of the semiconductor device after forming isolation region 200 and etching performed in order to form gate trench 310. FIG. 2B shows a state of the semiconductor device after silicon oxide film 21 is formed on the inner surfaces of gate trench 310 by thermal oxidation and silicon oxide film (ALD-SiO₂ film) 22 is formed on the inner surfaces by an ALD method.

As illustrated in FIG. 2A, an isolation trench is first formed in semiconductor substrate 100, and then silicon nitride film (LP-SiN film) 30 is formed by an LP-CVD (Low Pressure Chemical Vapor Deposition) method. Thereafter, silicon nitride film 30 is removed by etch-back, so that the upper surface thereof becomes recessed below the upper surface of active region 101 to form the upper portion of the gate trench. Next, a step in the trench for STI is filled with silicon oxide film (HDP-SiO₂ film) 20 formed by an HDP-CVD (High Density Plasma Chemical Vapor Deposition) method. Thus, there is formed isolation region 200. At this time, a bowing shape arises on a side surface of isolation region 200, and therefore, seam E2 occurs in silicon nitride film 30 corresponding to the lower layer of isolation region 200. This seam E2 is plugged up with silicon oxide film 20 corresponding to the upper layer of isolation region 200. This seam E2 appears, however, on a side surface of a portion of gate trench 310 intersecting with isolation region 200 when gate trench 310 is opened using mask film 301 as a mask.

Next, as illustrated in FIG. 2B, semiconductor substrate 100 is thermally oxidized to form silicon oxide film 21 (second insulating film) on the inner surfaces of each gate trench 310 as gate insulating film 311. Then, ALD-SiO₂ film 22 (first insulating film) superior in coverage is formed on the entire surface of semiconductor substrate 100 including the inner surfaces of gate trench 310. ALD-SiO₂ film 22 covers the inner surfaces of gate trench 310. At this time, ALD-SiO₂ film 22 is formed so as to have a thickness (for example, 5 nm) required for a gate insulating film and plug up seam E2 exposed on the inner surfaces of gate trench 310. Next, ALD-SiO₂ film 22 formed on the entire surface of semiconductor substrate 100 including the inner surfaces of gate trench 310 is further oxidized by heat treatment in an oxidative atmosphere to make the film denser. Note that ALD-SiO₂ film 22 may be additionally plasma-nitrided.

As described above, in the present exemplary embodiment, seam E2 is plugged up with ALD-SiO₂ film 22 (corresponding to “E2/22” in FIG. 1D).

That is, ALD-SiO₂ film 22 covers seam E2 exposed at the sidewall of gate trench 310. Accordingly, barrier metal layer 312a and metal layer 312b are prevented from taping into as far as seam E2 at the time of forming word line 300 in a later step. Thus, it is possible to prevent adjacent word lines 300 from short-circuiting to each other. As a result, it is possible to prevent yield decline. In addition, since ALD-SiO₂ film 22 can be formed on the inner surface of seam E2 and onto the inner surfaces of gate trench 310 at the same time, it is possible to minimize an increase in the number of steps.

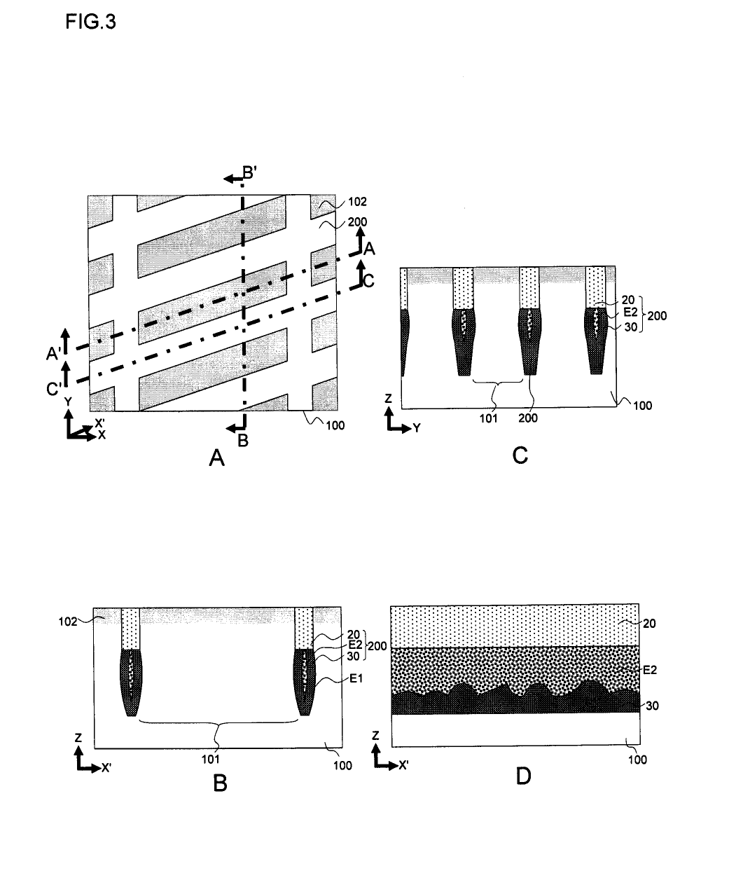

Next, a method for manufacturing the semiconductor device of the present exemplary embodiment will be described using FIGS. 3 to 11. Note that in each figure, a view denoted by “A” represents a plan view, whereas views denoted by “B”, “C” and “D” represent cross-sectional views respectively taken along the A-A′, B-B′ and C-C′ directions of View A.

First, as illustrated in FIG. 3, isolation trenches are formed on semiconductor substrate 100 by a heretofore-known method. Next, a field insulator made of silicon nitride film 30 and silicon oxide film 20 is formed so as to fill the isolation trenches, thus forming isolation regions 200. The field insulator may comprises at least one material selected from the group consisting of silicon oxide, silicon oxynitride and silicon nitride. At this time, a bowing shape arises on side surface E1 of each isolation trench, and seam E2 occurs in the central part of silicon nitride film 30. As illustrated in FIG. 3D, this seam E2 extends along the extending direction (X′ direction) of isolation region 200. Next, an impurity is implanted into the surface of active region 101 to form SD (source and drain) diffusion layers 102.

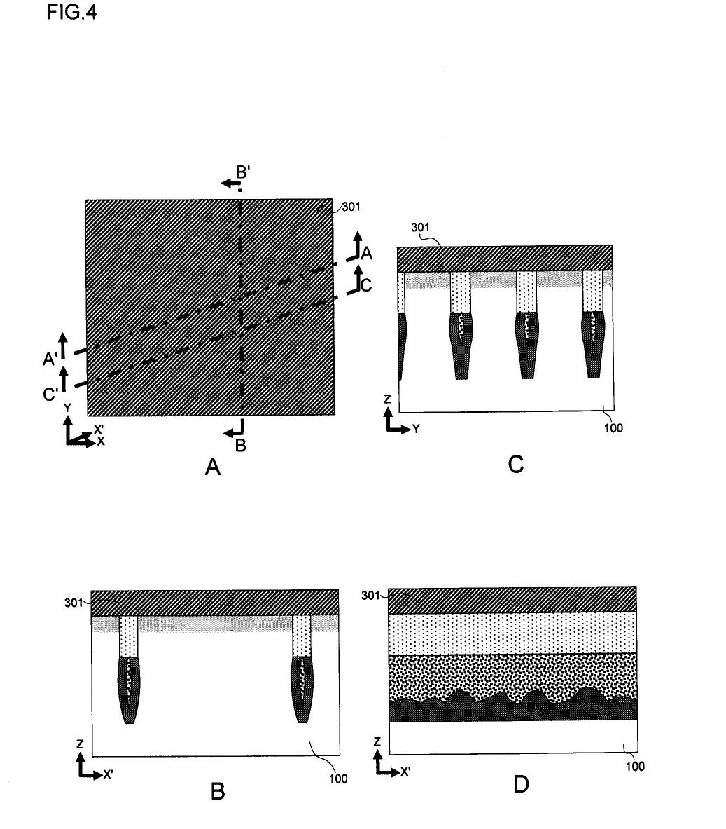

As illustrated in FIG. 4, mask film 301 made of a silicon nitride film is formed on the entire surface of semiconductor substrate 100.

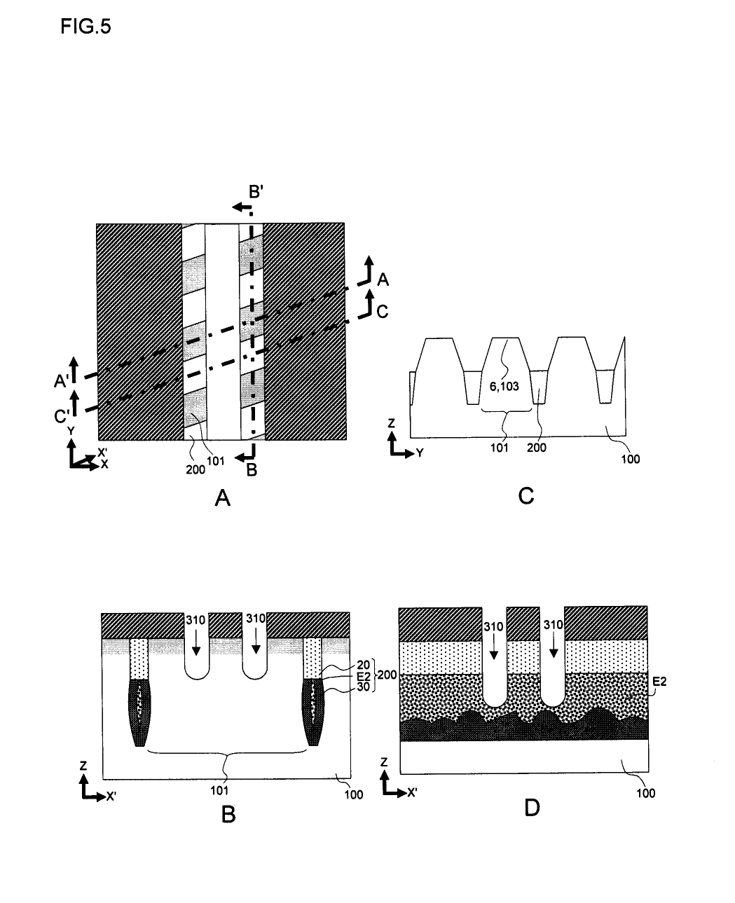

As illustrated in FIG. 5, gate trenches 310 extending continuously from active region 101 to isolation region 200 in the Y direction are opened in semiconductor substrate 100 by using lithography and dry etching techniques. At this time, the etching conditions are adjusted, so that each gate trench 310 is shallow in active region 101 and deep in isolation region 200. These etching conditions are set, however, so that the depth of the deepest portion of each gate trench 310 is smaller than the depth of isolation region 200. Consequently, there is formed convex active region 101 protruding upward from isolation region 200. Active region 101 left over in a saddle shape within gate trench 310 as described above is referred to as saddle fin 6. A surface of the saddle fin serves as channel 103 when a transistor is in an ON state. As illustrated in FIG. 5A, each gate trench 310 extends in the Y direction, whereas each isolation region 200 extends in the X′ direction. Accordingly, as illustrated in FIG. 5D, seam E2 extending in the X′ direction within isolation region 200 appears on the sidewalls of gate trench 310 in a location where gate trench 310 and isolation region 200 intersect with each other. That is, seam E2 extends from the sidewalls of one gate trench 310 to the sidewalls of another gate trench 310 in the isolation region 200 which is located between the adjacent gate trenches 310. In addition, both ends of seam E2 are located on the inner surfaces of the one and another gate trenches 310 which are the sidewalls thereof.

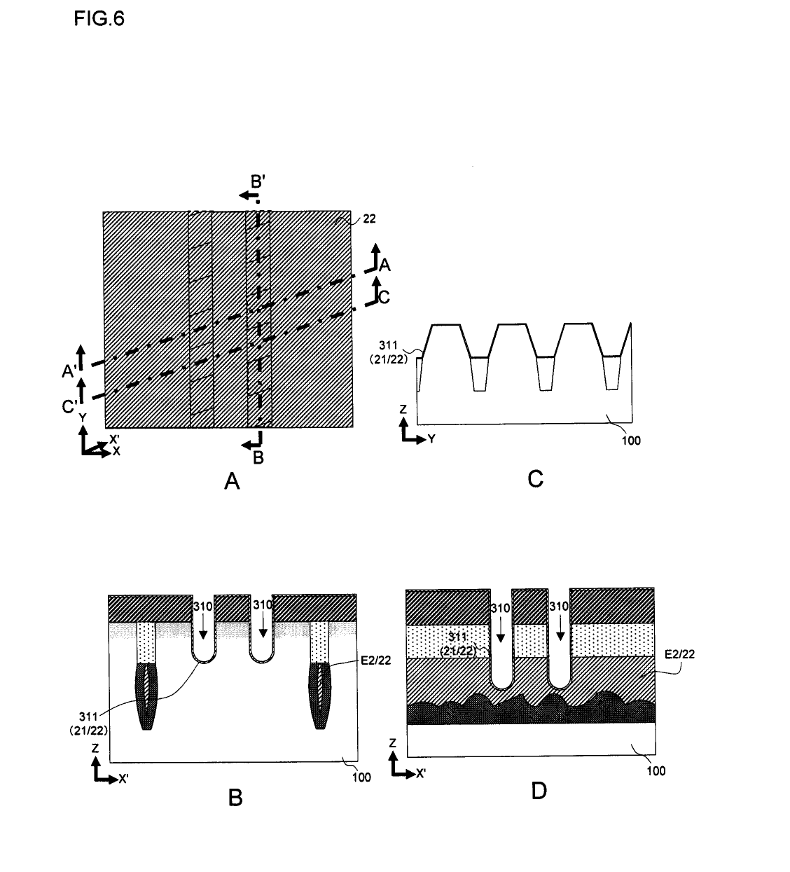

As illustrated in FIG. 6, an exposed surface of semiconductor substrate 100 including the inner surfaces of gate trenches 310 is thermally oxidized to form silicon oxide film 21 (second insulating film). Next, an insulating film superior in coverage, for example, ALD-SiO₂ film 22 (first insulating film) is formed on the entire surface of semiconductor substrate 100 including the inner surfaces of gate trenches 310 to a thickness (for example, 5 nm) required for a gate insulating film. At this time, ALD-SiO₂ film 22 is formed so as to plug up seam E2. Next, ALD-SiO₂ film 22 is further oxidized to make the film denser. Consequently, there is formed gate insulating film 311 made of silicon oxide film 21 and ALD-SiO₂ film 22. Gate insulating film covers both ends of seam E2.

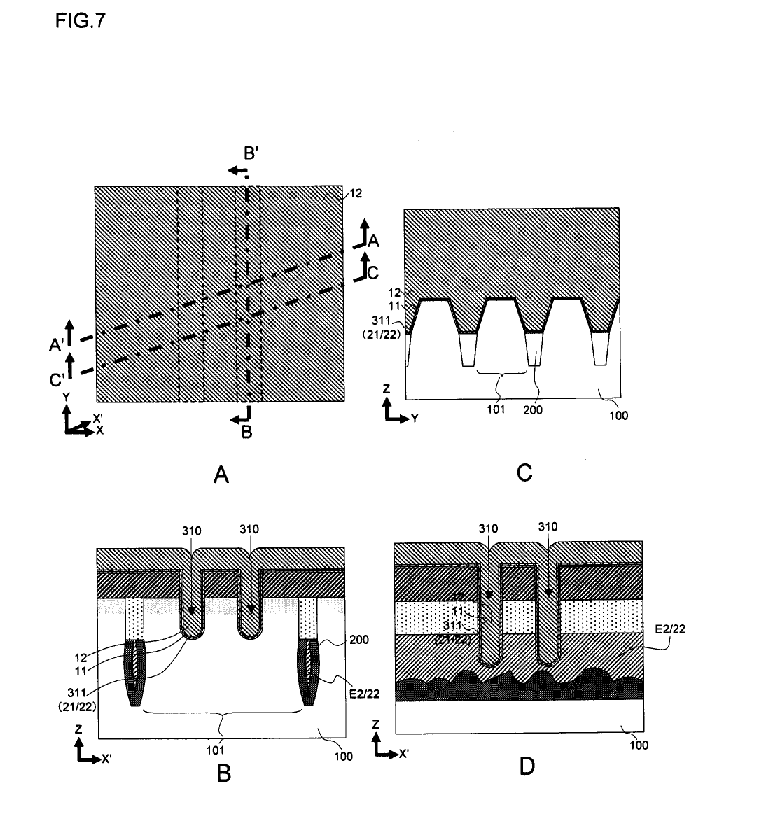

As illustrated in FIG. 7, thin titanium nitride film 11 and tungsten film 12 are formed on the entire surface of semiconductor substrate 100 including the inner surfaces of gate trenches 310. At this time, these films are formed so as to fill gate trenches 310. As described above, ALD-SiO₂ film 22 is formed on the inner surfaces of each gate trench 310, and seam E2 in isolation region 200 is plugged up with ALD-SiO₂ film 22. Accordingly, it is possible to prevent these films from being formed within seam E2 as well at the time of forming titanium nitride film 11 and tungsten film 12. As a result, it is possible to prevent adjacent buried word lines 300 to be formed in a later step from short-circuiting to each other.

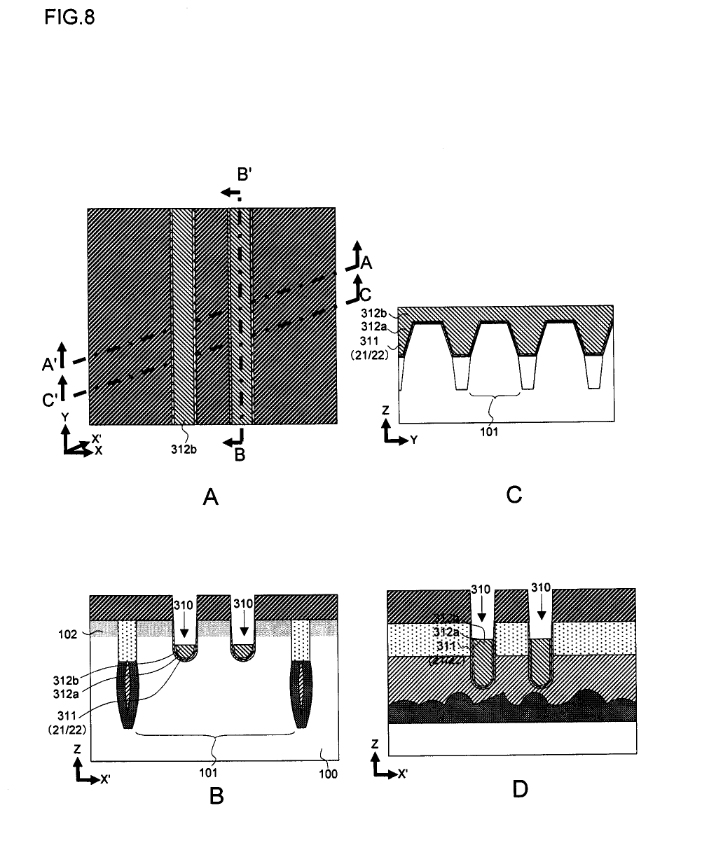

As illustrated in FIG. 8, titanium nitride film 11 and tungsten film 12 are etched back to leave over these films only on the bottom of each gate trench 310. That is, the upper surfaces of titanium nitride film 11 and tungsten film 12 are backed away so as to become recessed below the upper surface of active region 101 to form the upper portions of the gate trenches. Consequently, there are formed metal layer 312b made of the tungsten film and barrier metal layer 312a made of the titanium nitride film. Metal layer 312b and barrier metal layer 312a constitute a first conductive layer. At this time, the tungsten film which is metal layer 312b is formed so that the upper surface thereof is positioned below the lower end of SD diffusion layer 102.

Note that a portion of gate insulating film 311 exposed above tungsten film 12 in the upper portion of gate trench 310 is also abraded and thinned by this etch-back.

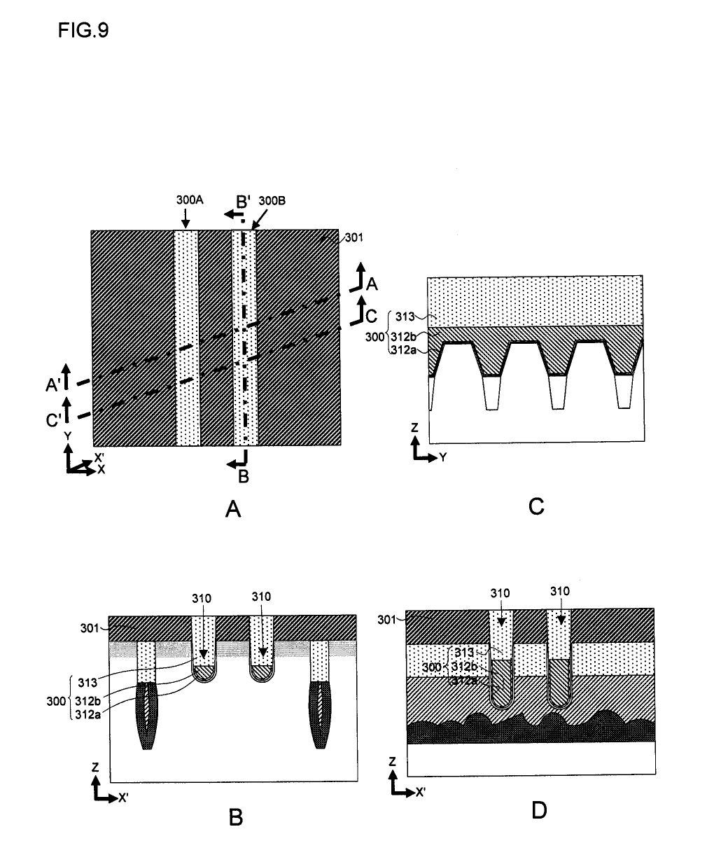

As illustrated in FIG. 9, cap insulating film 313 which is a silicon oxide film is formed so as to fill gate trenches 310. Thereafter, cap insulating film 313 is polished by CMP using mask film 301 as a stopper film. Consequently, there is completed buried word line 300 (shown as 300A and 300B in FIG. 9A) made of barrier metal layer 312a, metal layer 312b and cap insulating film 313.

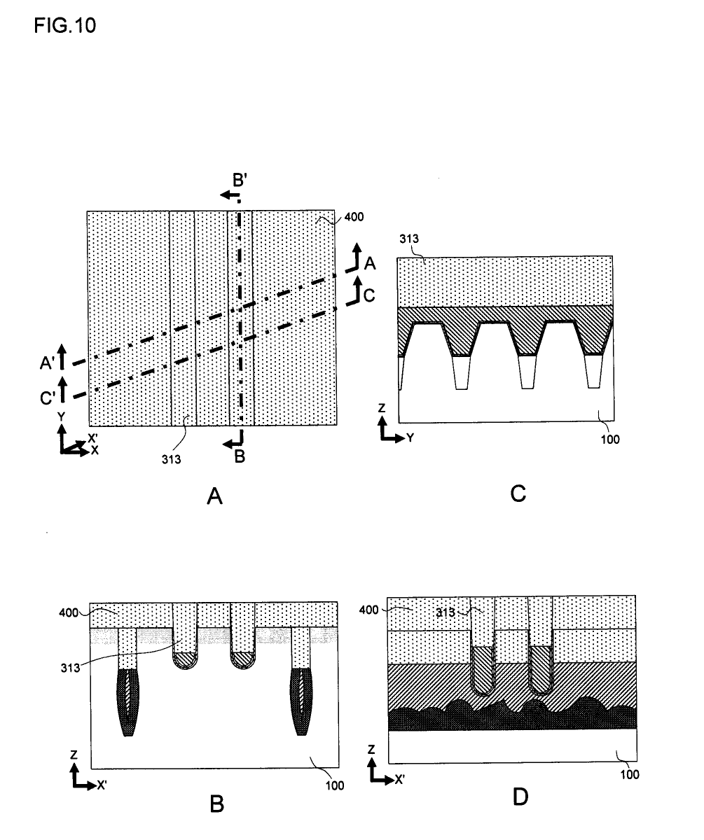

As illustrated in FIG. 10, mask film 301 made of a silicon nitride film is removed by wet etching. As a result, cap insulating film 313 which is a silicon oxide film protrudes from the surface of semiconductor substrate 100. Next, first interlayer insulating film 400 which is a silicon oxide film is formed on the entire surface of semiconductor substrate 100, so as to bury in space between protrusions of cap insulating film 313, and is then planarized by CMP.

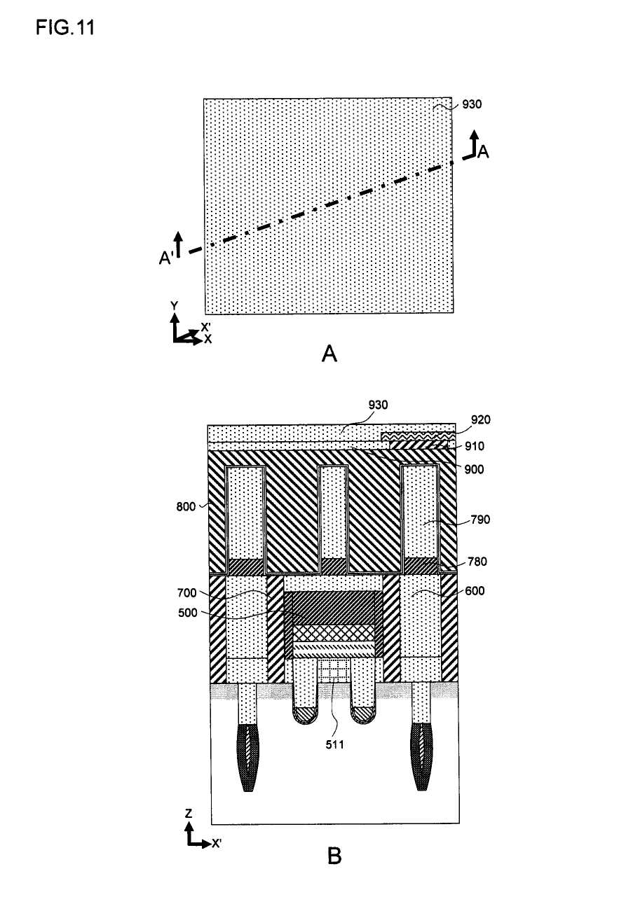

As illustrated in FIG. 11, there is formed bit-line contact plug 511, BL 500, second interlayer insulating film 600, capacitor contact plug 700, stopper film 780, third interlayer insulating film 790, capacitor 800, fourth interlayer insulating film 900, wiring contact 910, wiring line 920, and protective insulating film 930 by heretofore-known methods. Consequently, the semiconductor device of the present exemplary embodiment is completed.

Note that in the above-described exemplary embodiment, insulating film 22 is formed so as to fill the interiors of seam E2. Insulating film 22 has only to be such, however, as to plug up the opening of seam E2 (opening of the inner sidewall surfaces of gate trench 310 positioned inside isolation region 200, i.e., the opening shown by heavy line 10 in FIG. 1D) at least before barrier metal layer 312a is formed. Accordingly, insulating film 22 has only to function as a gate insulating film and has such a degree of coverage as to at least plug up the opening of seam E2.

In the above-described exemplary embodiment, ALD-SiO₂ film 22 is formed as insulating film 22. The material of insulating film 22 is not limited in particular, however, as long as the material can realize such a degree of coverage as to plug up the interiors of seam E2 and can be used as a gate insulating film. As insulating film 22, it is possible to use, for example, at least one type of film selected from the group consisting of a silicon oxide film, a silicon oxynitride film and a silicon nitride film formed by an ALD method, and a high-dielectric film (also known as a high-k film) higher in dielectric constant than the silicon dioxide film. Examples of the high-dielectric insulating film may include a film containing a metal oxide. More specifically, as the material of the high-dielectric insulating film, it is possible to use, for example, at least one type of insulating material selected from the group consisting of HfSiON, ZrO₂, Ta₂O₅, Nb₂O₅, Al₂O₃, HfO₂, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, Ho₂O₃, Er₂O₃, Tm₂O₃, Yb₂O₃, and Lu₂O₃. In addition, it is preferable to densify insulating film 22 by thermal oxidation after the formation of the film. In the above-described exemplary embodiment, metal layer 312b made of a tungsten film and barrier metal layer 312a made of a titanium nitride film are formed as the first conductive layer. The first conductive layer is not limited to these layers, however, but preferably contains at least one type of element selected from the group consisting of at least Ti, W and Ta.

It is apparent that the present invention is not limited to the above embodiments, but may be modified and changed without departing from the scope and spirit of the invention.

What is claimed is:

1. A semiconductor device comprising:
an isolation region buried with a field insulator;
an active region surrounded with the isolation region;
a first gate trench extending continuously from the active region to the isolation region;
a first insulating film covering an inner surface of the first gate trench in each of the active region and the isolation region;
a second insulating film interposing between the first insulating film and the inner surface of the first gate trench at the active region;
a first conductive layer burying a lower portion of the first gate trench so as to cover at least a part of the first insulating film and having an upper surface, the upper surface being placed below a surface of the active region; and
a cap insulating film covering the upper surface of the first conductive layer and burying an upper portion of the first gate trench.

2. The semiconductor device according to claim 1, further comprising:
a second gate trench extending continuously from the active region to the isolation region;
a first diffusion layer placed in the active region which is located between the first gate trench and the second gate trench;
second diffusion layers placed in the active region which are located on an opposite side of the first and second gate trenches adjacent to the first diffusion layer;
first and second contact plugs connected to the respective first and second diffusion layers, respectively; and
second and third conductive layers connected to the respective first and second contact plugs, respectively.

3. The semiconductor device according to claim 2,
wherein a seam extends from a sidewall of the first gate trench to a sidewall of the second gate trench in the field insulator at the isolation region which is located between the first gate trench and the second gate trench.

4. The semiconductor device according to claim 3,
wherein the first insulating film covers the seam exposed at the sidewall of the first gate trench.

5. The semiconductor device according to claim 4,
wherein the field insulator and the first insulating film comprise silicon nitride and silicon oxide, respectively.

6. The semiconductor device according to claim 1,
wherein the field insulator comprises at least one of silicon oxide and silicon nitride.

7. The semiconductor device according to claim 1,
wherein the first insulating film comprises at least one material selected from the group consisting of silicon oxide, silicon oxynitride and silicon nitride.

8. The semiconductor device according to claim 1,
wherein the first insulating film includes a metal oxide.

9. The semiconductor device according to claim 1,
wherein the first conductive layer includes at least one element selected from the group consisting of Ti, W and Ta.

10. The semiconductor device according to claim 2,
wherein the first, second and third conductive layers function as a word line, a bit line and a lower electrode, respectively.

11. The semiconductor device according to claim 10, further comprising:
a capacitor insulating film covering the lower electrode; and
an upper electrode covering the capacitor insulating film,
wherein the lower electrode, the capacitor insulating film and the upper electrode function as a capacitor for memory cell.

12. A semiconductor device comprising:
an active region surrounded with a field insulator;
first and second transistors disposed in the active region, the first and second transistors including first and second gate electrodes which are buried in first and second gate trenches, respectively, each of the first and second gate trenches extending continuously from the active region to the field insulator;
a first gate insulating film covering each of inner surfaces of the first and second gate trenches, the first gate insulating film extending continuously from the active region to the field insulator; and
a second gate insulating film interposing between the first gate insulating film and the inner surface of the first gate trench and between the first gate insulating film and the inner surface of the second gate trench at the active region.

13. The semiconductor device according to claim 12, further comprising:
a first diffusion layer which is a common drain region of each of the first and second transistors;
second diffusion layers which are respective source regions of the first and second transistors;
first, and second contact plugs connected to the first, and second diffusion layers, respectively; and
second, and third conductive layers connected to a corresponding one of first, and second contact plugs, respectively.

14. The semiconductor device according to claim 13,
wherein a seam is located in the field insulator between the first and second gate trenches, each end of the seam being positioned on the respective inner surfaces of the first and second gate trenches.

15. The semiconductor device according to claim 14,
wherein the first gate insulating film covers both ends of the seam.

16. The semiconductor device according to claim 15,
wherein the field insulator and the first gate insulating film include silicon nitride and silicon oxide, respectively.

17. A semiconductor device comprising:
an isolation region;
a field insulator including first and second trenches having respective inner surfaces, the field insulator being buried in the isolation region and a seam extending continuously from the inner surface of the first trench to the inner surface of the second trench in the field insulator;
an insulating film covering both ends of the seam; and
a first conductive layer covering the insulating film.
